(19) United States
(12) Patent Application Publication
(10) Pub. No.: US 2024/0120712 A1
(43) Pub. Date: Apr. 11, 2024

(54) SEMICONDUCTOR LASER ELEMENT AND LASER MODULE

(71) Applicant: HAMAMATSU PHOTONICS K.K., Hamamatsu-shi, Shizuoka (JP)

(72) Inventors: Kousuke TORII, Hamamatsu-shi, Shizuoka (JP); Kyogo KANEKO, Hamamatsu-shi, Shizuoka (JP)

(73) Assignee: HAMAMATSU PHOTONICS K.K., Hamamatsu-shi, Shizuoka (JP)

(21) Appl. No.: 18/265,287

(22) PCT Filed: Oct. 15, 2021
(86) PCT No.: PCT/JP2021/038249

§ 371 Date: Jun. 5, 2023

(30) Foreign Application Priority Data
Jan. 29, 2021 (JP) 2021-013640

(51) Int. Cl. H01S 5/20; H01S 5/02218; H01S 5/30; H01S 5/343; H01S 5/40

(52) U.S. Cl. CPC H01S 5/2031; H01S 5/02218; H01S 5/3095; H01S 5/34313; H01S 5/34353; H01S 5/4043; H01S 2301/18

(57) ABSTRACT

A semiconductor laser element includes a first emitter having a first active layer and a first guide layer, and a second emitter having a second active layer and a second guide layer. A thickness of the first emitter is different from a thickness of the second emitter so that an average value of an index DB1 and an index DB2 represented by equations (1) and (2) is 5% or less,

[Equation 1]

DB1=∫|F₁(θ)−F₀₁(θ)|dθ (1)

[Equation 2]

DB2=∫|F₂(θ)−F₀₂(θ)|dθ (2)

F₁(θ) is a far field pattern when it is assumed that only the first emitter is present, and F₂(θ) is a far field pattern when it is assumed that only the second emitter is present. F₀₁(θ) is a far field pattern of one of two modes corresponding to a fundamental mode of the light emitted from the first and second emitters, and F₀₂(θ) is a far field pattern of the other one.

### TECHNICAL FIELD

One aspect of the present disclosure relates to a semiconductor laser element and a laser module.

### BACKGROUND ART

As a semiconductor laser element, one in which a plurality of emitters (light-emitting parts) each including an active layer are stacked in a stacking direction is known (refer to, for example, Patent Literature 1). In such a semiconductor laser element, light from the plurality of emitters can be used as output light, and high output can be achieved.

### CITATION LIST

### Patent Literature

[Patent Literature 1] Japanese Unexamined Patent Publication No. H6-90063

### SUMMARY OF INVENTION

### Technical Problem

In the semiconductor laser element as described above, interference between lights from the plurality of emitters may cause disturbance in a far field pattern of the output light in the stacking direction. Since such disturbance can cause spatial unevenness in the output light, deviation from an optical design, and the like, it is desired to curb the disturbance.

An object of one aspect of the present disclosure is to provide a semiconductor laser element and a laser module capable of curbing disturbance in a far field pattern of output light.

### Solution to Problem

A semiconductor laser element according to one aspect of the present disclosure includes a first element part, and a second element part stacked on the first element part in a stacking direction, wherein the first element part includes a first emitter that includes a first active layer and a pair of first guide layers sandwiching the first active layer, and emits light along an optical axis direction, and a pair of first clad layers that sandwich the pair of first guide layers, the second element part includes a second emitter that includes a second active layer and a pair of second guide layers sandwiching the second active layer, and emits light along the optical axis direction, and a pair of second clad layers that sandwich the pair of second guide layers, and a thickness of the first emitter is different from a thickness of the second emitter so that an average value of an index DB1 represented by Equation (1) and an index DB2 represented by Equation (2) is 5% or less.

[Equation 1]

DB1=∫F₁(θ)−F₀₁(θ)|dθ (1)

[Equation 2]

DB2=∫|F₂(θ)−F₀₂(θ)|dθ (2)

In Equation (1) and Equation (2), θ is an angle with respect to the optical axis direction, F₁(θ), F₂(θ), F₀₁(θ) and F₀₂(θ) are normalized far field patterns in the stacking direction, F₁(θ) is a far field pattern of light emitted from the first emitter when it is assumed that the second emitter is not present and only the first emitter is present, and F₂(θ) is a far field pattern of light emitted from the second emitter when it is assumed that the first emitter is not present and only the second emitter is present, and when only the first emitter and second emitter are present, and it is assumed that, among two modes corresponding to a fundamental mode of the light emitted from the first emitter and the second emitter, a mode with a smaller propagation constant is defined as a first mode, and a mode with a larger propagation constant is defined as a second mode, F₀₁(θ) is a far field pattern in the first mode, and F₀₂(θ) is a far field pattern in the second mode when the thickness of the first emitter is thinner than the thickness of the second emitter, and F₀₁(θ) is a far field pattern in the second mode, and F₀₂(θ) is the far field pattern in the first mode when the thickness of the first emitter is thicker than the thickness of the second emitter.

In the semiconductor laser element, the thickness of the first emitter may be different from the thickness of the second emitter so that the average value of the index DB1 and the index DB2 is 5% or less. Thus, it is possible to curb interference between lights emitted from the first emitter and the second emitter and thus to curb disturbance of the far field pattern of output light.

The thickness of the first emitter may be different from the thickness of the second emitter so that the average value of the index DB1 and the index DB2 is 3% or less. In this case, the interference between the lights emitted from the first emitter and the second emitter can be effectively curbed.

The thickness of the first emitter may be different from the thickness of the second emitter so that the average value of the index DB1 and the index DB2 is 1% or less. In this case, the interference between the lights emitted from the first emitter and the second emitter can be more effectively curbed.

The thickness of the first emitter is different from the thickness of the second emitter due to a total thickness of the pair of first guide layers being different from a total thickness of the pair of second guide layers. In this case, the degree of freedom in designing the thicknesses of the first active layer and the second active layer can be increased. For example, the thicknesses of the first active layer and the second active layer can be made equal to each other.

The thickness of the first emitter may be different from the thickness of the second emitter so that an index P represented by Equation (3) is 25 or more. In this case, the interference between the lights emitted from the first emitter and the second emitter can be curbed.

[Equation 3]

P=|β₁−β₂|/K₁₂ (3)

in Equation (3), β₁ is a propagation constant of the first emitter, β₂ is a propagation constant of the second emitter, and K₁₂ is a coupling constant between the first emitter and the second emitter when it is assumed that the thickness of each of the first emitter and the second emitter is equal to an average thickness of the first emitter and the second emitter.

The thickness of the first emitter may be different from the thickness of the second emitter so that the index P is 40 or more. In this case, the interference between the lights emitted from the first emitter and the second emitter can be effectively curbed.

The thickness of the first emitter may be different from the thickness of the second emitter so that the index P is 125 or more. In this case, the interference between the lights emitted from the first emitter and the second emitter can be more effectively curbed.

An absolute difference between the thickness of the first emitter and the average thickness of the first emitter and the second emitter may be 10% or less of the average value. In this case, it is possible to curb deterioration of quality of output light due to an excessive thickness difference between the first emitter and the second emitter.

The semiconductor laser element according to one aspect of the present disclosure may further include a third element part stacked on the second element part in the stacking direction, wherein the third element part includes a third emitter that includes a third active layer and a pair of third guide layers sandwiching the third active layer, and emits light along the optical axis direction, and a pair of third clad layers sandwiching the pair of third guide layers, and a thickness of the third emitter is different from the thickness of the second emitter so that an average value of an index DB3 represented by Equation (4) and an index DB4 represented by Equation (5) is 5% or less. In this case, the interference between the lights emitted from the second emitter and the third emitter can be curbed.

[Equation 4]

DB3=∫|F₃(θ)−F₀₃(θ)|dθ (4)

[Equation 5]

DB4=∫|F₄(θ)−F₀₄(θ)|dθ (5)

In Equation (4) and Equation (5), F₃(θ) is a far field pattern of light emitted from the third emitter when it is assumed that the first and second emitters are not present and only the third emitter is present, and F₄(θ) is a far field pattern of light emitted from the second emitter when it is assumed that the first and third emitters are not present and only the second emitter is present, and when the first emitter is not present and only the second emitter and the third emitter are present and it is assumed that, among two modes corresponding to a fundamental mode of the light emitted from the second emitter and the third emitter, a mode with a smaller propagation constant is defined as a third mode, and a mode with a larger propagation constant is defined as a fourth mode, F₀₃(θ) is a far field pattern in the third mode, and F₀₄(θ) is a far field pattern in the fourth mode when the thickness of the third emitter is thinner than the thickness of the second emitter, and F₀₃(θ) is a far field pattern in the fourth mode, and F₀₄(θ) is a far field pattern in the third mode when the thickness of the third emitter is thicker than the thickness of the second emitter. The semiconductor laser element according to one aspect of the present disclosure may further include a substrate, wherein the first emitter and the second emitter may be stacked on the substrate so that the first emitter is located on a first side closer to the substrate than the second emitter, and the thickness of the first emitter may be thinner than the thickness of the second emitter. In this case, it is possible to avoid a situation in which an effect of curbing light interference described above is impaired due to an influence of strain that occurs in the first emitter and the second emitter due to a force acting from the substrate. The laser module of the present invention includes the semiconductor laser element and the mount member on which the semiconductor laser element is mounted, the semiconductor laser element is fixed to the mount member on the second side opposite to the first side, and a thermal expansion coefficient of the mount member is smaller than a thermal expansion coefficient of the substrate. In the laser module, it is possible to avoid the situation in which the above-described effect of curbing light interference is impaired due to the influence of the strain that occurs in the first emitter and the second emitter due to forces acting from the substrate and the mount member.

A laser module according to one aspect of the present disclosure includes the semiconductor laser element, and a mount member on which the semiconductor laser element is mounted, wherein the semiconductor laser element further includes a substrate, the first emitter and the second emitter are stacked on the substrate so that the first emitter is located on a first side closer to the substrate than the second emitter, the semiconductor laser element is fixed to the mount member on a second side opposite to the first side, a thermal expansion coefficient of the mount member is larger than a thermal expansion coefficient of the substrate, and the thickness of the first emitter is thicker than the thickness of the second emitter. In the laser module, it is possible to avoid a situation in which the above-described effect of curbing the interference of light is impaired due to the influence of the strain that occurs in the first emitter and the second emitter due to the forces acting from the substrate and the mount member.

A semiconductor laser element according to one aspect of the present disclosure includes a first element part, and a second element part stacked on the first element part in a stacking direction, wherein the first element part includes a first emitter that includes a first active layer and a pair of first guide layers sandwiching the first active layer, and emits light along an optical axis direction, and a pair of first clad layers sandwiching the pair of first guide layers, the second element part includes a second emitter that is stacked on the first emitter in the stacking direction, includes a second active layer and a pair of second guide layers sandwiching the second active layer, and emits light along the optical axis direction, and a pair of second clad layers sandwiching the pair of second guide layers, and a thickness of the first emitter is different from a thickness of the second emitter so that an index P represented by Equation (6) is 25 or more,

[Equation 6]

P=|β₁−β₂|/K₁₂ (6)

in Equation (6), β₁ is a propagation constant of the first emitter, β₂ is a propagation constant of the second emitter, and K₁₂ is a coupling constant between the first emitter and the second emitter when it is assumed that the thickness of each of the first emitter and the second emitter is equal to an average thickness of the first emitter and the second emitter.

In the semiconductor laser element, the thickness of the first emitter is different from the thickness of the second emitter so that the index P is 25 or more. Thus, it is possible to curb the interference between the lights emitted from the first emitter and the second emitter and thus to curb the disturbance of the far field pattern of the output light.

### Advantageous Effects of Invention

According to one aspect of the present disclosure, it is possible to provide a semiconductor laser element and a laser module capable of curbing disturbance in a far field pattern of output light.

### BRIEF DESCRIPTION OF DRAWINGS

FIG. 1 is a cross-sectional view of a semiconductor laser element according to an embodiment.

FIG. 2(a) is a graph showing a far field pattern of output light from a semiconductor laser element according to a comparative example, and FIG. 2(b) is a graph showing a far field pattern of output light from the semiconductor laser element according to the embodiment.

FIGS. 3(a) and 3(b) are graphs showing calculation examples of changes in the far field pattern with respect to an index DBa.

FIG. 4 is a graph showing a relationship between an index P and the index DBa.

FIG. 5 is a cross-sectional view of a simplified semiconductor laser element.

FIG. 6 is a cross-sectional view of a semiconductor laser element according to a modified example.

FIG. 7 is a diagram showing a mounting state of the semiconductor laser element.

FIG. 8 is a diagram showing another example of the mounting state of the semiconductor laser element.

### DESCRIPTION OF EMBODIMENTS

An embodiment of the present disclosure will be described in detail below with reference to the accompanying drawings. In the following description, the same reference numerals are used for the same or corresponding elements, and overlapping descriptions will be omitted.

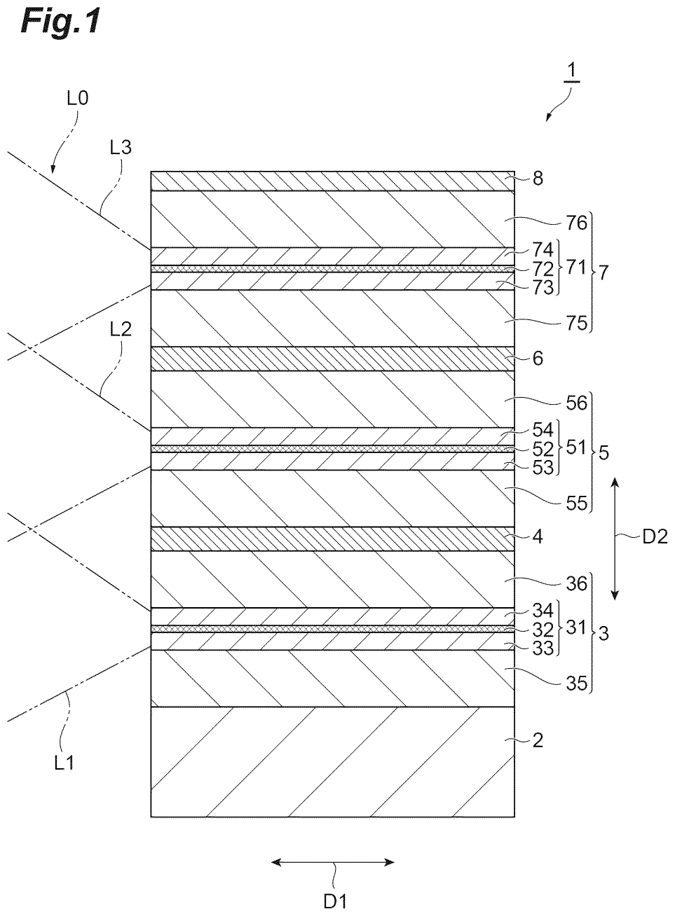

As shown in FIG. 1, a semiconductor laser element 1 includes a substrate 2, a first element part 3, a first tunnel junction layer 4, a second element part 5, a second tunnel junction layer 6, a third element part 7, and a cap layer 8. The first element part 3, the first tunnel junction layer 4, the second element part 5, the second tunnel junction layer 6, the third element part 7, and the cap layer 8 are stacked in this order on the substrate 2 in a stacking direction D2 (a thickness direction of the substrate 2). Each of the layers can be formed on the substrate 2 by an epitaxial growth method.

The semiconductor laser element 1 is an end-surface emission type laser diode that emits output light L0 in an optical axis direction D1 (a lengthwise direction of the substrate 2) from one end surface in the optical axis direction D1 perpendicular to the stacking direction D2. The semiconductor laser element 1 is configured as a multi junction type (a stacked type) in which a plurality of emitters (a first emitter 31, a second emitter 51 and a third emitter 71) each including an active layer are stacked via tunnel junctions (a first tunnel junction layer 4 and a second tunnel junction layer 6). The semiconductor laser element 1 can be used for flash light detection and ranging (LiDAR) or the like that requires a relatively high pulse output.

The substrate 2 is a semiconductor substrate made of n-type GaAs. The first element part 3 has a first emitter 31 and a pair of first clad layers 35 and 36. The first emitter 31 includes a first active layer 32 and a pair of first guide layers 33 and 34. The first guide layers 33 and 34 sandwich the first active layer 32 in the stacking direction D2. The first clad layers 35 and 36 sandwich the first active layer 32 and the first guide layers 33 and 34 in the stacking direction D2. The first clad layer 35, the first guide layer 33, the first active layer 32, the first guide layer 34, and the first clad layer 36 are stacked on the substrate 2 in this order. A buffer layer is provided between the first clad layer 35 and the substrate 2.

The first active layer 32 includes a barrier layer and a pair of quantum well layers that sandwich the barrier layer in the stacking direction D2, and has a double quantum well structure. The barrier layer is made of Al_{0.28}GaAs and has a thickness of 5 nm. Each of the quantum well layers is made of In_{0.1}Al_{0.049}GaAs and has a thickness of 8 nm.

Each of the first guide layers 33 and 34 is made of Al_{0.28}GaAs and has a thickness of (70−d) nm. In this example, d=4 and each of the first guide layers 33 and 34 has a thickness of 66 nm. That is, the total thickness of the first guide layers 33 and 34 is β₂ mn, and the first emitter 31 has a thickness of 153 nm. A refractive index of each of the first guide layers 33 and 34 is lower than that of the first active layer 32 and higher than that of each of the first clad layers 35 and 36. The first clad layer 35 is made of n-type Al_{0.37}GaAs and has a thickness of 1600 nm. The first clad layer 36 is made of p-type Al_{0.37}GaAs and has a thickness of 2000 nm. The first tunnel junction layer 4 is made of GaAs and has a thickness of 225 nm.

The second element part 5 is stacked on the first element part 3 with the first tunnel junction layer 4 interposed therebetween. The second element part 5 includes a second emitter 51 and a pair of second clad layers 55 and 56. The second emitter 51 includes a second active layer 52 and a pair of second guide layers 53 and 54. The second guide layers 53 and 54 sandwich the second active layer 52 in the stacking direction D2. The second clad layers 55 and 56 sandwich the second active layer 52 and the second guide layers 53 and 54 in the stacking direction D2. The second clad layer 55, the second guide layer 53, the second active layer 52, the second guide layer 54, and the second clad layer 56 are stacked in this order on the first tunnel junction layer 4. That is, the second emitter 51 is stacked on the first emitter 31 with the first clad layer 36, the first tunnel junction layer 4, and the second clad layer 55 interposed therebetween.

The second active layer 52 has the same configuration as the first active layer 32. That is, the second active layer 52 includes a barrier layer and a pair of quantum well layers that sandwich the barrier layer in the stacking direction D2, and has a double quantum well structure. The barrier layer is made of Al_{0.28}GaAs and has a thickness of 5 nm. Each of the quantum well layers is made of In_{0.1}Al_{0.049}GaAs and has a thickness of 8 nm. A thickness of the second active layer 52 is equal to the thickness of the first active layer 32.

Each of the second guide layers 53 and 54 is made of Al_{0.28}GaAs and has a thickness of 70 nm. That is, the total thickness of the second guide layers 53 and 54 is 140 nm, and the second emitter 51 has a thickness of 161 nm. A refractive index of each of the second guide layers 53 and 54 is lower than that of the second active layer 52 and higher than that of each of the second clad layers 55 and 56. The second clad layer 55 is made of n-type Al_{0.37}GaAs and has a thickness of 2000 nm. The second clad layer 56 is made of p-type Al_{0.37}GaAs and has a thickness of 2000 nm. The second tunnel junction layer 6 is made of GaAs and has a thickness of 225 nm.

The third element part 7 is stacked on the second element part 5 with the second tunnel junction layer 6 interposed therebetween. The third element part 7 includes a third emitter 71 and a pair of third clad layers 75 and 76. The third emitter 71 includes a third active layer 72 and a pair of third guide layers 73 and 74. The third guide layers 73 and 74 sandwich the third active layer 72 in the stacking direction D2. The third clad layers 75 and 76 sandwich the third active layer 72 and the third guide layers 74 and 74 in the stacking direction D2. The third clad layer 75, the third guide layer 73, the third active layer 72, the third guide layer 74 and the third clad layer 76 are stacked in this order on the second tunnel junction layer 6. That is, the third emitter 71 is stacked on the second emitter 51 with the second clad layer 56, the second tunnel junction layer 6, and the third clad layer 75 interposed therebetween.

The third active layer 72 has the same configuration as the first active layer 32 and the second active layer 52. That is, the third active layer 72 includes a barrier layer and a pair of quantum well layers that sandwich the barrier layer in the stacking direction D2, and has a double quantum well structure. The barrier layer is made of Al_{0.28}GaAs and has a thickness of 5 nm. Each of the quantum well layers is made of In_{0.1}Al_{0.049}GaAs and has a thickness of 8 nm. A thickness of the third active layer 72 is equal to the thickness of each of the first active layer 32 and the second active layer 52.

Each of the third guide layers 73 and 74 is made of Al_{0.28}GaAs and has a thickness of (70+d) nm. In this example, d=4 and each of the third guide layers 73 and 74 has a thickness of 74 nm. That is, the total thickness of the third guide layers 73 and 74 is 148 nm, and the third emitter 71 has a thickness of 169 nm. A refractive index of each of the third guide layers 73 and 74 is lower than that of the third active layer 72 and higher than that of each of the third clad layers 75 and 76. The third clad layer 75 is made of n-type Al_{0.37}GaAs and has a thickness of 2000 nm. The third clad layer 76 is made of p-type Al_{0.37}GaAs and has a thickness of 2000 nm. The cap layer 8 is made of n-type GaAs and has a thickness of 200 mn.

During an operation of the semiconductor laser element 1, for example, a voltage is applied between electrodes provided on a surface of the substrate 2 opposite to the first element part 3 and on the cap layer 8. Thus, light is generated in the first active layer 32, the second active layer 52, and the third active layer 72. The light generated in the first active layer 32 is confined within the first emitter 31 (the first active layer 32 and the first guide layers 33 and 34), is also reflected by both end surfaces of the first emitter 31 in the optical axis direction D1 and amplified while reciprocating between the end surfaces, and is emitted from one end surface as a laser beam L1 in the optical axis direction D1. Similarly, laser beams L2 and L3 are output from the second emitter 51 and the third emitter 71 in the optical axis direction D1. The output light L0 of the semiconductor laser element 1 is configured of the laser beams L1, L2, and L3. In this example, an oscillation wavelength of each of the laser beams L1, L2, and L3 is 905 nm. Thus, the first emitter 31, the second emitter 51 and the third emitter 71 output light in the same wavelength range.

As described above, in the semiconductor laser element 1, the thicknesses of the first emitter 31, the second emitter 51, and the third emitter 71 are 153 nm, 161 nm, and 169 nm, respectively, the thickness of the first emitter 31 is different from the thickness of the second emitter 51, and the thickness of the third emitter 71 is different from the thickness of the second emitter 51. More specifically, since the total thickness (β₂ nm) of the first guide layers 33 and 34 is different from the total thickness (140 nm) of the second guide layers 53 and 54, the thickness of the first emitter 31 is different from the thickness of the second emitter 51. Further, since the total thickness (148 nm) of the third guide layers 73 and 74 is different from the total thickness (140 nm) of the second guide layers 53 and 54, the thickness of the third emitter 71 is different from the thickness of the second emitter 51. Thus, interference between the laser beams L1, L2, and L3 emitted from the first emitter 31, the second emitter 51, and the third emitter 71 can be curbed, and disturbance of a far field pattern of the output light L0 can be curbed. This point will be further described below.

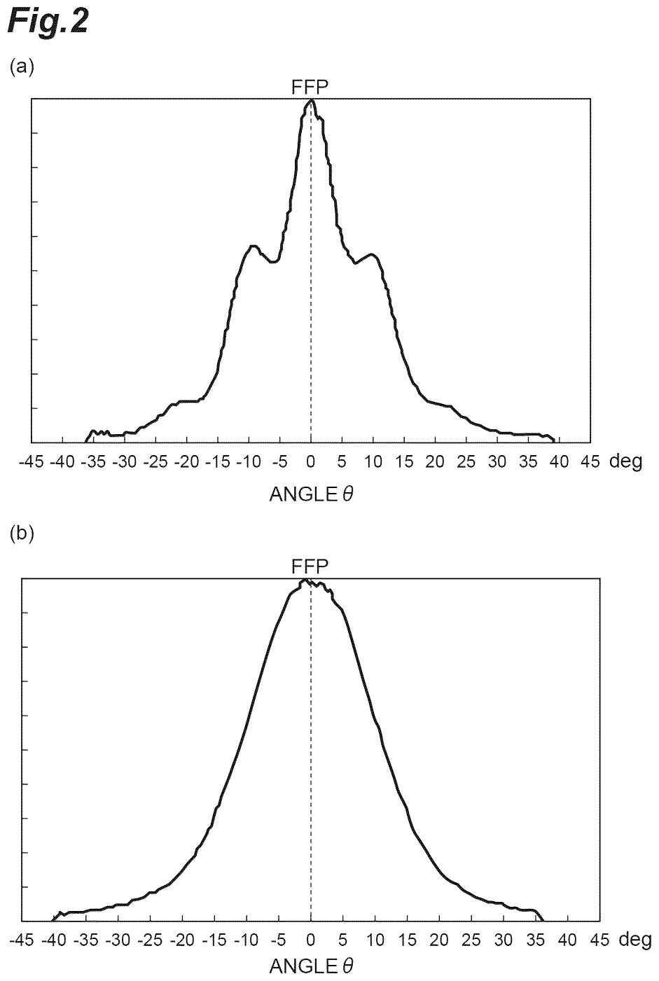

FIG. 2(a) is a graph showing a far field pattern (FFP) of output light from a semiconductor laser element according to a comparative example, and FIG. 2(b) is a graph showing a far field pattern of output light from the semiconductor laser element 1 according to the embodiment. FIGS. 2(a) and 2(b) show measured data of the far field pattern in the stacking direction D2 (a crystal growth direction). An angle θ is an angle in the stacking direction D2 with respect to the optical axis direction D1. The far field pattern is a light intensity distribution at a position sufficiently far from a light emission surface. The semiconductor laser element according to the comparative example is different from the semiconductor laser element 1 only in that the thicknesses of the first guide layers 33 and 34 and the third guide layers 73 and 74 are equal to the thicknesses of the second guide layers 53 and 54. That is, the semiconductor laser element according to the comparative example corresponds to a case in which the parameter d is set to 0 in the semiconductor laser element 1.

As shown in FIGS. 2(a) and 2(b), in the comparative example, while the comparative example had disturbance (unevenness) in the far field pattern, the semiconductor laser element 1 according to the embodiment did not have such disturbance. This is because, in the comparative example, the interference between the laser beams L1, L2, and L3 from the first emitter 31, the second emitter 51, and the third emitter 71 causes beats, but in the semiconductor laser element 1 according to the embodiment, the interference between the laser beams L1, L2, and L3 is curbed. From this, it can be understood that the interference between the laser beams L1, L2, and L3 can be curbed by varying the thicknesses of the first emitter 31, the second emitter 51, and the third emitter 71, and thus the disturbance of the far field pattern of the output light L0 can be curbed.

How to set the thicknesses of the first emitter 31, the second emitter 51 and the third emitter 71 in order to curb the interference between the laser beams L1, L2 and L3 will be described. In the following, attention will be paid to an effect of the interference between the laser beams L1 and L2 from the first emitter 31 and the second emitter 51 on the far field pattern of the output light L0.

An average value of an index DB1 represented by Equation (7) and an index DB2 represented by Equation (8) is assumed to be an index DBa. That is, DBa=(DB1+DB2)/2. The index DBa indicates how much of an area surrounded by the far field pattern of the output light L0 is modulated by the interference.

[Equation 7]

DB1=∫|F₁(θ)−F₀₁(θ)|dθ (7)

[Equation 8]

DB2=|F₂(θ)−F₀₂(θ)|dθ (8)

In Equations (7) and (8), θ is an angle with respect to the optical axis direction D1. An integration range is a full range of radiation angles (irradiation angles), for example from −90° to +90°. F₁(θ), F₂(θ), F₀₁(θ) and F₀₂(θ) are the normalized far field patterns in the stacking direction D2 and are all normalized so that an integrated value is 1 over the entire range of the radiation angle in the stacking direction D2. F₁(θ) is the far field pattern of the laser beam L1 emitted from the first emitter 31 when it is assumed that the second emitter 51 and the third emitter 71 (emitters other than the first emitter 31) are not present and only the first emitter 31 is present alone. F₂(θ) is the far field pattern of the laser beam L2 emitted from the second emitter 51 when it is assumed that the first emitter 31 and the third emitter 71 (emitters other than the second emitter 51) are not present and only the second emitter 51 is present alone.

When the third emitter 71 is not present and only the first emitter 31 and second emitter 51 are present, among two modes corresponding to fundamental modes of the light (the output light L0) emitted from the first emitter 31 and the second emitter 51, a mode with a smaller propagation constant is defined as a first mode, and a mode with a larger propagation constant is defined as a second mode. When the thickness of the first emitter 31 is thinner than the thickness of the second emitter 51, F₀₁(θ) is the far field pattern of the first mode, and F₀₂(θ) is the far field pattern of the second mode. When the thickness of the first emitter 31 is thicker than the thickness of the second emitter 51, F₀₁(θ) is the far field pattern of the second mode, and F₀₂(θ) is the far field pattern of the first mode.

That is, when only two emitters including the first emitter 31 and the second emitter 51 are present, the output light L0 has two modes as fundamental modes. Among the two modes, a mode with the smaller propagation constant is defined as a first mode, and a mode with the larger propagation constant is defined as a second mode. In the semiconductor laser element 1, the thickness of the first emitter 31 is thinner than the thickness of the second emitter 51. Therefore, F₀₁(θ) is the far field pattern of the first mode, and F₀₂(θ) is the far field pattern of the second mode. When the thickness of the first emitter 31 is thicker than the thickness of the second emitter 51 as in a modified example described below, F₀₁(θ) is the far field pattern of the second mode, and F₀₂(θ) is the far field pattern of the first mode. Hereinafter, the description of (θ) in the far field patterns F₁(θ), F₂(θ), F₀₁(θ), and F₀₂(θ), and the like will be omitted as appropriate.

The reason for changing the far field pattern to be compared in accordance with a size relationship between the thicknesses of the first emitter 31 and the second emitter 51 is as follows. When the thicknesses of the first emitter 31 and the second emitter 51 are different from each other, the far field patterns when each of the first emitter 31 and the second emitter 51 is present alone have different widths. Also, the far field patterns when each of the first emitter 31 and the second emitter 51 is present alone have base widths different from those in the two modes that occur when the first emitter 31 and the second emitter 51 are present simultaneously. The indexes DB1 and DB2 calculated by Equations (7) and (8) are affected not only by the interference but also by a difference in width between the far field patterns. Therefore, in order to accurately evaluate a degree of interference, the far field patterns with similar base widths are compared.

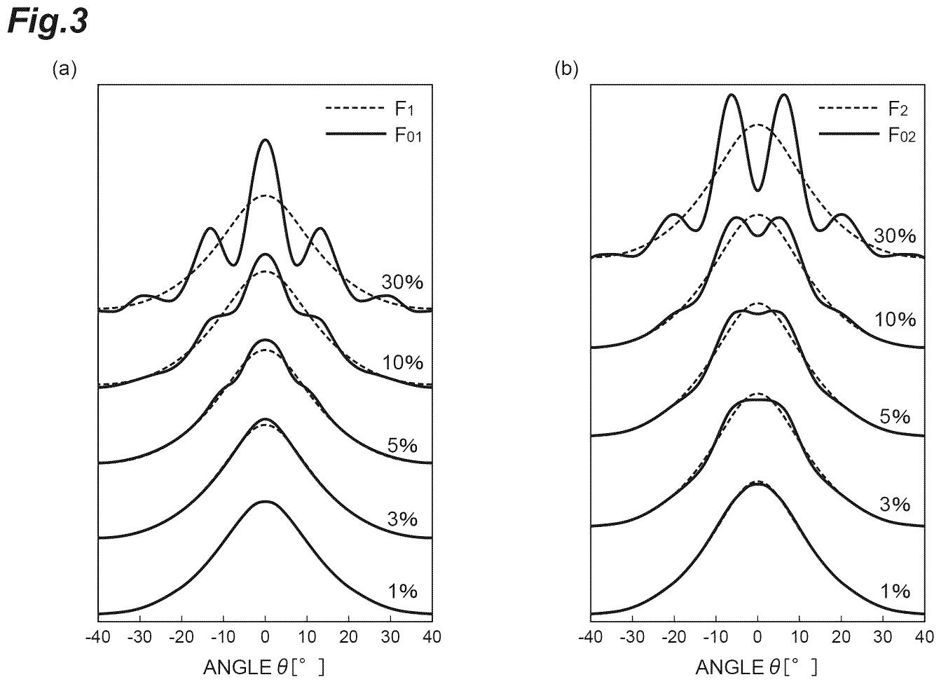

FIGS. 3(a) and 3(b) are graphs showing calculation examples of changes in the far field pattern with respect to the index DBa when the thickness of the first emitter 31 is thinner than the thickness of the second emitter 51. In FIG. 3(a), the far field pattern F₁ (the far field pattern in the absence of interference) is indicated by a dashed line, and the far field pattern F₀₁ is indicated by a solid line. In FIG. 3(b), the far field pattern F₂ (the far field pattern in the absence of interference) is indicated by a dashed line, and the far field pattern F₀₂ is indicated by a solid line. FIGS. 3(a) and 3(b) show the far field patterns F₁, F₀₁, F₂, and F₀₂ in order from the bottom when the index DBa is 1%, 3%, 5%, 10%, and 30%.

As shown in FIGS. 3(a) and 3(b), when the index DBa is 10% or 30%, the far field patterns F₀₁ and F₀₂ are disturbed. On the other hand, when the index DBa is 1%, 3%, and 5%, the far field patterns F₀₁ and F₀₂ are not disturbed, or even when they are disturbed, the disturbance is curbed. As the index DBa becomes smaller, shapes of the far field patterns F₀₁ and F₀₂ are closer to those of the far field patterns F₁ and F₂, and thus the occurrence of disturbance is effectively curbed. Therefore, the interference between the laser beams L1 and L2 emitted from the first emitter 31 and the second emitter 51 can be curbed by making the thickness of the first emitter 31 different from the thickness of the second emitter 51 so that the index DBa is 5% or less, and thus the disturbance of the far field pattern of the output light L0 can be curbed. Specifically, as a difference (an absolute difference) in thickness between the first emitter 31 and the second emitter 51 increases, the effect of curbing the interference between the laser beams L1 and L2 increases. Therefore, the interference between the laser beams L1 and L2 can be curbed by setting the difference in thickness between the first emitter 31 and the second emitter 51 so that the index DBa is 5% or less.

Further, as shown in FIG. 3(a), when the index DBa is 5%, a peak portion of the far field pattern F₀₁ is slightly recessed, whereas when the index DBa is 3% or less, only one extremum is present in the central portion of the far field pattern F₀₁. Therefore, the index DBa is preferably 3% or less. Also, when the index DBa is 1%, the shapes of the far field patterns F₀₁ and F₀₂ substantially coincide with the far field patterns F₁ and F₂. Therefore, it is more preferable that the index DBa is 1% or less.

A preferable upper limit of the difference in the thickness between the first emitter 31 and the second emitter 51 will be described. As the difference in the thickness between the first emitter 31 and the second emitter 51 becomes larger, the effect of curbing the interference increases, but as described above, the difference in the width of the far field pattern when each of the first emitter 31 and the second emitter 51 is present alone is large. When the difference in the widths of the far field pattern is large, practical problems may occur. Therefore, the absolute difference between the thickness of the first emitter 31 and the average thicknesses of the first emitter 31 and the second emitter 51 can be set to 10% or less of the average value. This is for the following reasons. There is generally an inverse proportion relationship between widths of a far field pattern and a near field pattern. Also, the width of the near field pattern depends on a thickness of the guide layer. A degree of dependence may vary according to a structure thereof, but a region in which a 10% change in the width of the near field pattern occurs for a 10% change in the thickness of the guide layer is large. As a change in the width of the far field pattern, about ±10% can be practically allowed. Therefore, the above conditions are set.

An index P represented by Equation (9) is set as an index related to the index DBa.

[Equation 9]

P=|β₁−β₂|/K₁₂ (9)

In Equation (9), β₁ is a propagation constant of the first emitter 31. β₂ is a propagation constant of the second emitter 51. K₁₂ is a coupling constant between the first emitter 31 and the second emitter 51 when it is assumed that the thickness of each of the first emitter 31 and the second emitter 51 is equal to the average thickness of the first emitter 31 and the second emitter 51.

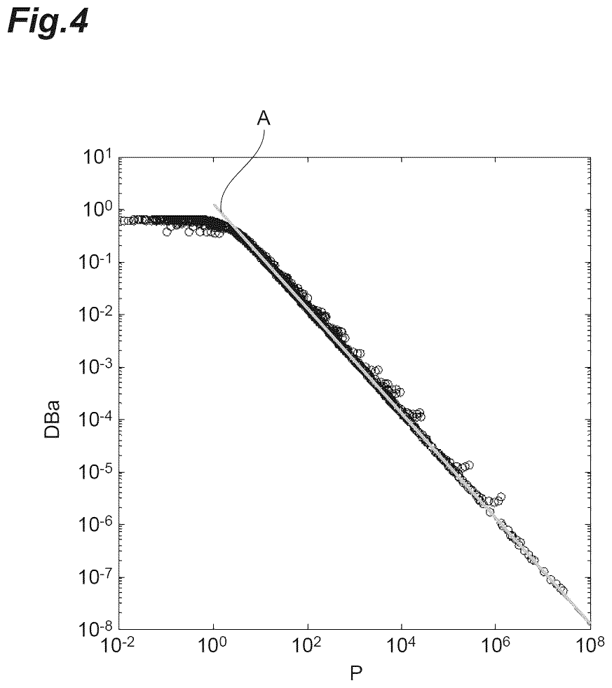

FIG. 4 is a graph showing a relationship between the index P and the index DBa. FIG. 4 shows a straight line A that indicates DBa=1.25/P. Each plot is a calculation result obtained by variously changing the structures of the first emitter 31 and the second emitter 51. As shown in FIG. 4, many plots are located on or near the straight line A, and there is a good correlation between the index DBa and the index P. The present inventors found out that there is the good correlation between the index DBa and the index P. From this graph, it can be seen that the index P should be set to 25 or more to make the index DBa 5% or less, the index P should be set to 40 or more to make the index DBa 3% or less, and the index P should be set to 125 or more to make the index DBa 1% or less.

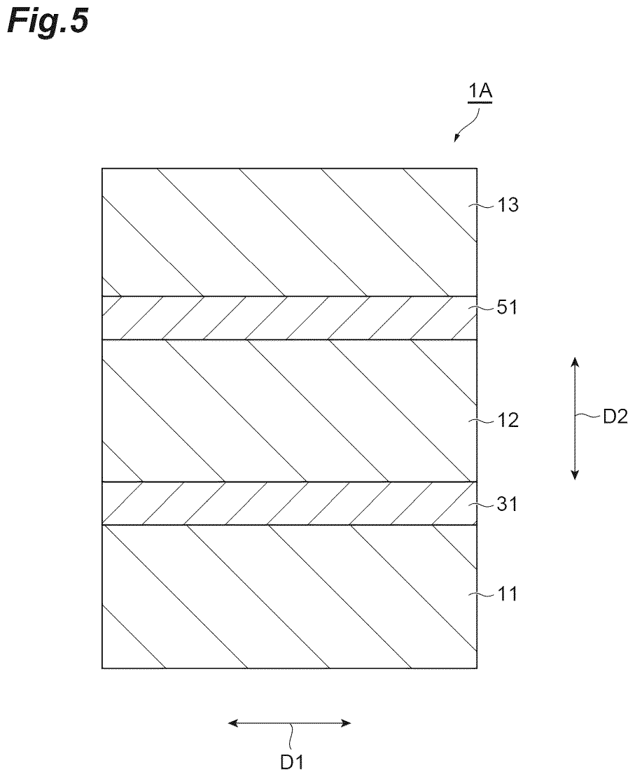

A method of calculating the propagation constants β₁ and β₂ and the coupling constant K₁₂ will be described. In calculations below, the first emitter 31 and the second emitter 51 are analyzed as slab type waveguides. First, a semiconductor laser element 1A simplified as shown in FIG. 5 is considered. In the semiconductor laser element 1A, a clad layer 11, a first emitter 31, a clad layer 12, a second emitter 51 and a clad layer 13 are stacked in this order. A refractive index of each of the clad layers 11, 12, and 13 is set to no, and the thickness of the clad layer 12 is set to D. It is assumed that the thickness of each of the clad layers 11 and 13 is semi-infinite. A refractive index of each of the first guide layers 33 and 34 and the second guide layers 53 and 54 is set to n₁, and a thickness of each of the first guide layers 33 and 34 and the second guide layers 53 and 54 is set to a. An oscillation wavelength of each of the first emitter 31 and the second emitter 51 is set to λ.

When the laser beams L1 and L2 emitted from the first emitter 31 and the second emitter 51 are TE mode light, the propagation constants β of the first emitter 31 and the second emitter 51 are calculated as follows.

Equation (10) defines v. In Equation (10), k is a wave number in vacuum and is equal to 2π/λ.

[Equation 10]

v²=a²k²(n₁²−n₀²) (10)

b is determined by solving Equation (11). b may be determined by reading from a graph that represents the relationship between v and b.

$$\\ \begin{matrix}[ Equation 11 ] & \\ v \sqrt{1 - b} = {tan}^{- 1} ( \sqrt{\frac{b}{1 - b}} ) & ( 11 )\end{matrix}$$

The propagation constants 13 are calculated by Equation (12).

[Equation 12]

β=k\sqrt{(n₁²−n₀²)b+n₀²} (12)

The coupling constant K₁₂ between the first emitter 31 and the second emitter 51 when it is assumed that the thickness of each of the first emitter 31 and the second emitter 51 is equal to the average thickness of the first emitter 31 and the second emitter 51 can be calculated as follows.

u and w are defined by Equations (13) and (14).

[Equation 13]

u²=a²(k²n₁²−β²) (13)

[Equation 14]

w²=a²(β²−k²n₀²) (14)

The coupling constant K₁₂ is calculated from Equation (15).

$$\\ \begin{matrix}[ Equation 15 ] & \\ {K}_{12} = \frac{{u}^{2} {w}^{2}}{{a}^{2} β ( 1 + w ) {v}^{2}} exp ( - \frac{wD}{a} ) & ( 15 )\end{matrix}$$

When the laser beams L1 and L2 emitted from the first emitter 31 and the second emitter 51 have TM mode, the propagation constants β of the first emitter 31 and the second emitter 51 are calculated by a calculation method in which Equation (11) is replaced with Equation (16) and Equation (15) is replaced with Equation (17) in the above calculation method. That is, the index DBa and the index P are calculated using either the calculation method when the laser beams L1 and L2 have the TM mode or the calculation method when the laser beams L1 and L2 have the TE mode.

$$\\ \begin{matrix}[ Equation 16 ] & \\ v \sqrt{1 - b} = {tan}^{- 1} ( \frac{{n}_{1}^{2}}{{n}_{0}^{2}} \sqrt{\frac{b}{1 - b}} ) & ( 16 )\end{matrix}$$

$$\\ \begin{matrix}[ Equation 17 ] & \\ {K}_{12} = \frac{β {n}_{0}^{2} {u}^{2} {w}^{2}}{2 {a}^{2} {k}^{2} \{ \begin{matrix}( {n}_{1}^{2} + {n}_{0}^{2} w ) {n}_{0}^{2} {u}^{2} + \\ ( {n}_{0}^{2} + {n}_{1}^{2} w ) {n}_{1}^{2} {w}^{2}\end{matrix} \}} exp ( - \frac{wD}{a} - w ) \{ ( 1 + \frac{{n}_{0}^{2}}{{n}_{1}^{2}} ) exp ( w ) + ( 1 - \frac{{n}_{0}^{2}}{{n}_{1}^{2}} ) exp ( - w ) \} & ( 17 )\end{matrix}$$

In actual calculations, the propagation constants β and the coupling constant K₁₂ are calculated by the above calculation method using definitions below without simplifying the semiconductor laser element 1.
n₁: a weighted average value of refractive indices of the guide layer and the active layer weighted by the thickness so that, as the layers become thicker, the weight becomes greater
n₀: a weighted average value of the refractive indices of the clad layers weighted by the thickness so that as the layers become thicker, the weight becomes greater
2a: average thickness of two target emitters (total thickness of the active layer and the pair of guide layers)
D: total thickness of the clad layer and the tunnel junction layer disposed between the emitters

As described above, the thicknesses of the first emitter 31 and the second emitter 51 can be set using the index DBa and the index P. The effect of the interference between the laser beams L2 and L3 from the second emitter 51 and the third emitter 71 and the interference between the laser beams L1 and L3 from the first emitter 31 and the third emitter 71 on the far field pattern of the output light L0 is similar to the effect of the interference between the laser beams L1 and L2 from the first emitter 31 and the second emitter 51 on the far field pattern of the output light L0. However, since a distance between the first emitter 31 and the third emitter 71 in the stacking direction D2 is greater than a distance between the first emitter 31 and the second emitter 51 and a distance between the second emitter 51 and the third emitter 71, the effect of the interference between the laser beams L1 and L3 is sufficiently small compared to the effect of the interference between the laser beams L1 and L2 and the effect of the interference between the laser beams L2 and L3, and thus can be ignored.

The interference between the laser beams L2 and L3 emitted from the second emitter 51 and the third emitter 71 can be curbed by making the thickness of the third emitter 71 different from the thickness of the second emitter 51 so that the index DBb, which is the average value of the index DB3 represented by Equation (18) and the index DB4 represented by Equation (19), is 5% or less, and thus the disturbance of the far field pattern of the output light L0 can be curbed.

[Equation 18]

DB3=∫|F₃(θ)−F₀₃(θ)|dθ (18)

[Equation 19]

DB4=∫|F₄(θ)−F₀₄(θ)|dθ (19)

In Equations (18) and (19), F₃, F₄, F₀₃, and F₀₄ are normalized far field patterns in the stacking direction D2, all of which are normalized so that an integrated value for the entire range of the radiation angle in the stacking direction D2 is 1. F₃ is the far field pattern of the laser beam L3 emitted from the third emitter 71 when it is assumed that the first emitter 31 and the second emitter 51 are not present and only the third emitter 71 is present alone. F₄ is the far field pattern of the laser beam L2 emitted from the second emitter 51 when it is assumed that the first emitter 31 and the third emitter 71 are not present and only the second emitter 51 is present alone.

When the first emitter 31 is not present and only the second emitter 51 and third emitter 71 are present, among the two modes corresponding to the fundamental mode of the light (the output light L0) emitted from the second emitter 51 and the third emitter 71, the mode with a smaller propagation constant is defined as a third mode, and the mode with a larger propagation constant is defined as a fourth mode. When the thickness of the third emitter 71 is thinner than the thickness of the second emitter 51, F₀₃ is the far field pattern of the third mode, and F₀₄ is the far field pattern of the fourth mode. When the thickness of the third emitter 71 is thicker than the thickness of the second emitter 51, F₀₃ is the far field pattern of the fourth mode, and F₀₄ is the far field pattern of the third mode. In the semiconductor laser element 1, the thickness of the third emitter 71 is thicker than the thickness of the second emitter 51. Therefore, F₀₃(θ) is the far field pattern of the fourth mode, and F₀₄(θ) is the far field pattern of the third mode.

The index P for the second emitter 51 and the third emitter 71 is represented by Equation (20).

[Equation 20]

P=|β₃−β₂|/K₂₃ (20)

In Equation (20), β₃ is a propagation constant of the third emitter 71. β₂ is a propagation constant of the second emitter 51. K₂₃ is a coupling constant between the second emitter 51 and the third emitter 71 when it is assumed that the thickness of each of the second emitter 51 and the third emitter 71 is equal to the average thickness of the second emitter 51 and the third emitter 71.

In the semiconductor laser element 1 according to the embodiment, the index P for the first emitter 31 and the second emitter 51 and the index P for the second emitter 51 and the third emitter 71 are about 190 and are 125 or more. That is, the index DBa is 1% or less. The difference in the thickness between the first emitter 31 and the second emitter 51 is 8 nm, is 10% or less of 157 nm which is the average thickness of the first emitter 31 and the second emitter 51, and is also 10% or less of 161 nm which is the average thickness of the first emitter 31, the second emitter 51 and the third emitter 71 (the average thickness of all emitters). The difference in the thickness between the third emitter 71 and the second emitter 51 is 8 nm, is 10% or less of 165 nm which is the average thickness of the second emitter 51 and the third emitter 71, and is also 10% or less of 161 nm which is the average thicknesses of the first emitter 31, the second emitter 51 and the third emitter 71.

### [Function and Effect]

In the semiconductor laser element 1, the thickness of the first emitter 31 is different from the thickness of the second emitter 51 so that the index DBa that is an average value of the indices DB1 and DB2 is 5% or less. The effective refractive index and the propagation constant of the first emitter 31 and the second emitter 51 can be made different by modulating the thicknesses of the first emitter 31 and the second emitter 51 in this way. As a result, the interference (resonant coupling of propagation modes) of the laser beams L1 and L2 emitted from the first emitter 31 and the second emitter 51 can be curbed, and thus the disturbance of the far field pattern of the output light L0 can be curbed. As described above, the disturbance can cause spatial unevenness in the output light L0, deviation from the optical design, and the like. Moreover, such unevenness and deviation can cause a decrease in yield. On the other hand, in the semiconductor laser element 1, the yield can be improved by curbing the disturbance. Further, the disturbance in the far field pattern of the output light L0 can be also curbed by thickening the first clad layer 36 and the second clad layer 55 disposed between the first emitter 31 and the second emitter 51, but the operating voltage increases. In contrast, in the semiconductor laser element 1, the disturbance in the far field pattern of the output light L0 can be curbed while the increase in the operating voltage is curbed.

The thickness of the first emitter 31 is different from the thickness of the second emitter 51 so that the index DBa is 3% or less, more specifically 1% or less. Thus, the interference between the laser beams L1 and L2 can be effectively curbed.

Since the total thickness of the first guide layers 33 and 34 is different from the total thickness of the second guide layers, the thickness of the first emitter 31 is different from the thickness of the second emitter 51. Thus, a degree of freedom in designing the thicknesses of the first active layer 32 and the second active layer 52 can be increased, and for example, the thicknesses of the first active layer 32 and the second active layer 52 can be made equal to each other.

The thickness of the first emitter 31 is different from the thickness of the second emitter 51 so that the index P is 25 or more. Thus, the interference between the laser beams L1 and L2 can be curbed.

The thickness of the first emitter 31 is different from the thickness of the second emitter 51 so that the index P is 40 or more, more specifically 125 or more. Thus, the interference between the laser beams L1 and L2 can be effectively curbed.

The absolute difference between the thickness of the first emitter 31 and the average thicknesses of the first emitter 31 and the second emitter 51 is 10% or less of the average value. Thus, it is possible to curb deterioration of the quality of the output light L0 due to an excessive difference in the thickness between the first emitter 31 and the second emitter 51.

The thickness of the third emitter 71 is different from the thickness of the second emitter 51 so that the index DBb that is the average value of the indices DB3 and DB4 is 5% or less. Thus, interference between the laser beams L2 and L3 emitted from the second emitter 51 and the third emitter 71 can be curbed.

### Modified Examples

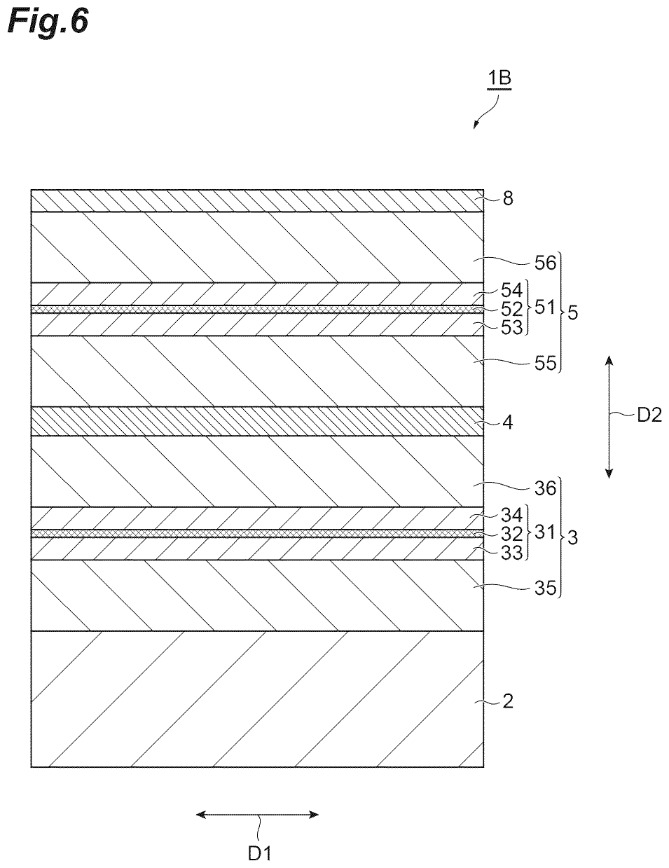

A semiconductor laser element 1B shown in FIG. 6 includes a substrate 2, a first element part 3, a first tunnel junction layer 4, a second element part 5 and a cap layer 8, but does not include the second tunnel junction layer 6 and the third element part 7. The first active layer 32 is configured of one quantum well layer made of In_{0.1}Al_{0.049}GaAs and having a thickness of 8 nm. Each of the first guide layers 33 and 34 is made of Al_{0.25}GaAs and has a thickness of (100−h) nm. The first clad layer 35 is made of n-type Al_{0.35}GaAs and has a thickness of 1600 nm. The first clad layer 36 is made of p-type Al_{0.35}GaAs and has a thickness of 1600 nm. The first tunnel junction layer 4 is made of GaAs and has a thickness of 200 nm.

The second active layer 52 is configured of one quantum well layer made of In_{0.1}Al_{0.049}GaAs and having a thickness of 8 nm. Each of the second guide layers 53 and 54 is made of Al_{0.25}GaAs and has a thickness of (100+h) nm. The second clad layer 55 is made of n-type Al_{0.35}GaAs and has a thickness of 1600 nm. The second clad layer 56 is made of p-type Al_{0.35}GaAs and has a thickness of 1600 nm. The cap layer 8 is made of n-type GaAs and has a thickness of 100 nm. The oscillation wavelength of each of the first emitter 31 and the second emitter 51 is 905 nm.

Table 1 shows results of numerical calculation when a parameter h is changed in the semiconductor laser element 1B. From Table 1, it can be seen that as the parameter h increases, the index P increases, the index DBa decreases, and the disturbance in the far field pattern of the output light L0 is curbed. As described above, according to the semiconductor laser element 1B, it is possible to curb the disturbance in the far field pattern of the output light L0, as in the above embodiment.

TABLE 1

| h [nm] | P | DBa [%] |
|---|---|---|
| 1 | 20.82 | 5.8 |
| 2 | 43.27 | 2.8 |
| 3 | 65.71 | 1.7 |
| 4 | 88.15 | 1.4 |
| 5 | 110.58 | 1.1 |

As another modified example, the semiconductor laser element 1B may be configured as follows. Each of the first guide layers 33 and 34 has a thickness of (400−h) nm, each of the first clad layers 35 and 36 has a thickness of 800 nm, each of the second guide layers 53 and 54 has a thickness of (400+h) nm, and each of the second clad layers 55 and 56 has a thickness of 800 nm. This modified example of the semiconductor laser element 1B is configured in the same manner as the semiconductor laser element 1B in other respects.

Table 2 shows the results of numerical calculation when the parameter h is changed in the modified example of the semiconductor laser element 1B. From Table 2, it can be seen that as the parameter h increases, the index P increases, the index DBa decreases, and the disturbance in the far field pattern of the output light L0 can be curbed. As described above, according to the modified example of the semiconductor laser element 1B, it is possible to curb the disturbance of the far field pattern of the output light L0, as in the above embodiment.

TABLE 2

| h [nm] | P | DBa [%] |
|---|---|---|
| 1 | 3.49 | 31.5 |
| 5 | 18.81 | 6.7 |
| 10 | 37.98 | 3.3 |
| 15 | 57.16 | 2.2 |
| 20 | 76.37 | 1.7 |
| 25 | 95.63 | 1.3 |

Tables 3 to 6 show calculation results of values of a thickness modulation amount (a₁−a₂)n₁/λ, when the index P is 40 in the semiconductor laser element 1A shown in FIG. 5. Tables 3, 4, 5 and 6 show cases in which the normalized refractive index difference (n₁−n₀)/n₁ is 0.02, 0.03, 0.04 and 0.05, respectively. In Tables 3 to 6, 2a₁ is the thickness of the first emitter 31, 2a₂ is the thickness of the second emitter 51, and 2a₀ is the average thickness of the first emitter 31 and the second emitter 51. n₁ is the refractive index of each of the first emitter 31 and the second emitter 51. a₀n₁/λ represents the average thickness of the emitter normalized by the wavelength and the refractive index, and (Dn₁/λ)*(a₀n₁/λ) represents the product of the average thickness of the emitter normalized by the wavelength and the refractive index, and the thickness of the clad layer normalized by the wavelength and the refractive index. Columns with numerical values in Tables 3 to 6 indicate that the thicknesses of the first emitter 31 and the second emitter 51 can be set so that the index P is 40. These points also apply to Tables 7 to 10 described below. According to such a semiconductor laser element 1A, it is also possible to curb the disturbance in the far field pattern of the output light L0, as in the above embodiment.

TABLE 3

| | | a₀n₁/λ | | | | | | | |
|---|---|---|---|---|---|---|---|---|---|
| (n₁ − n₀)/n₁ = 0.02 | | 0.35 | 0.5 | 0.75 | 1 | 1.25 | 1.5 | 1.75 | 2 |
| (Dn₁/λ) × | 1 | — | — | — | — | — | — | — | — |
| (a₀n₁/λ) | 2 | — | — | — | — | — | — | — | — |
| | 3 | — | — | — | — | — | — | 0.640 | 0.511 |
| | 4 | — | — | — | — | 0.408 | 0.280 | 0.199 | 0.147 |
| | 5 | — | — | — | 0.251 | 0.151 | 0.092 | 0.060 | 0.042 |
| | 6 | — | — | 0.190 | 0.106 | 0.055 | 0.030 | 0.018 | 0.012 |
| | 7 | — | — | 0.098 | 0.045 | 0.020 | 0.010 | 0.006 | 0.003 |
| | 8 | — | — | 0.050 | 0.019 | 0.007 | 0.003 | 0.002 | 0.001 |

TABLE 4

| | | a₀n₁/λ | | | | | | | |
|---|---|---|---|---|---|---|---|---|---|
| (n₁ − n₀)/n₁ = 0.03 | | 0.35 | 0.5 | 0.75 | 1 | 1.25 | 1.5 | 1.75 | 2 |
| (Dn₁/λ) × | 1 | — | — | — | — | — | — | — | — |
| (a₀n₁/λ) | 2 | — | — | — | — | — | 0.494 | 0.380 | 0.303 |
| | 3 | — | — | — | 0.219 | 0.129 | 0.082 | 0.057 | 0.042 |
| | 4 | — | 0.185 | 0.111 | 0.050 | 0.024 | 0.013 | 0.008 | 0.006 |
| | 5 | 0.087 | 0.084 | 0.033 | 0.011 | 0.005 | 0.002 | 0.001 | 0.001 |
| | 6 | 0.053 | 0.038 | 0.010 | 0.003 | 0.001 | <0.001 | <0.001 | <0.001 |
| | 7 | 0.033 | 0.017 | 0.003 | 0.001 | <0.001 | <0.001 | <0.001 | <0.001 |
| | 8 | 0.020 | 0.008 | 0.001 | <0.001 | <0.001 | <0.001 | <0.001 | <0.001 |

TABLE 5

| | | a₀n₁/λ | | | | | | | |
|---|---|---|---|---|---|---|---|---|---|
| (n₁ − n₀)/n₁ = 0.04 | | 0.35 | 0.5 | 0.75 | 1 | 1.25 | 1.5 | 1.75 | 2 |
| (Dn₁/λ) × | 1 | — | — | — | — | — | — | — | 0.798 |
| (a₀n₁/λ) | 2 | — | — | — | 0.238 | 0.146 | 0.098 | 0.071 | 0.055 |
| | 3 | — | 0.151 | 0.069 | 0.028 | 0.014 | 0.008 | 0.005 | 0.004 |
| | 4 | 0.067 | 0.044 | 0.012 | 0.003 | 0.001 | 0.001 | <0.001 | <0.001 |
| | 5 | 0.030 | 0.013 | 0.002 | <0.001 | <0.001 | <0.001 | <0.001 | <0.001 |
| | 6 | 0.014 | 0.004 | <0.001 | <0.001 | <0.001 | <0.001 | <0.001 | <0.001 |
| | 7 | 0.006 | 0.001 | <0.001 | <0.001 | <0.001 | <0.001 | <0.001 | <0.001 |
| | 8 | 0.003 | <0.001 | <0.001 | <0.001 | <0.001 | <0.001 | <0.001 | <0.001 |

TABLE 6

| | | a₀n₁/λ | | | | | | | |
|---|---|---|---|---|---|---|---|---|---|
| (n₁ − n₀)/n₁ = 0.05 | | 0.35 | 0.5 | 0.75 | 1 | 1.25 | 1.5 | 1.75 | 2 |
| (Dn₁/λ) × | 1 | — | — | — | — | — | 0.491 | 0.394 | 0.328 |
| (a₀n₁/λ) | 2 | — | — | 0.120 | 0.057 | 0.031 | 0.020 | 0.014 | 0.010 |
| | 3 | 0.074 | 0.043 | 0.011 | 0.003 | 0.001 | 0.001 | <0.001 | <0.001 |
| | 4 | 0.023 | 0.008 | 0.001 | <0.001 | <0.001 | <0.001 | <0.001 | <0.001 |
| | 5 | 0.007 | 0.001 | <0.001 | <0.001 | <0.001 | <0.001 | <0.001 | <0.001 |
| | 6 | 0.002 | <0.001 | <0.001 | <0.001 | <0.001 | <0.001 | <0.001 | <0.001 |
| | 7 | 0.001 | <0.001 | <0.001 | <0.001 | <0.001 | <0.001 | <0.001 | <0.001 |
| | 8 | <0.001 | <0.001 | <0.001 | <0.001 | <0.001 | <0.001 | <0.001 | <0.001 |

Tables 7 to 10 show calculation results of values of the thickness modulation amount (a₁−a₂)n₁/λ at which the index P is 125 in the semiconductor laser element 1A shown in FIG. 5. Tables 7, 8, 9 and 10 show cases in which the normalized refractive index difference (n₁−n₀)/n1 is 0.02, 0.03, 0.04 and 0.05, respectively.

TABLE 7

| | | a₀n₁/λ | | | | | | | |
|---|---|---|---|---|---|---|---|---|---|
| (n₁ − n₀)/n₁ = 0.02 | | 0.35 | 0.5 | 0.75 | 1 | 1.25 | 1.5 | 1.75 | 2 |
| (Dn₁/λ) × | 1 | — | — | — | — | — | — | — | — |
| (a₀n₁/λ) | 2 | — | — | — | — | — | — | — | — |
| | 3 | — | — | — | — | — | — | — | — |
| | 4 | — | — | — | — | — | — | 0.608 | 0.456 |
| | 5 | — | — | — | — | 0.464 | 0.287 | 0.188 | 0.131 |
| | 6 | — | — | — | 0.331 | 0.172 | 0.095 | 0.057 | 0.038 |
| | 7 | — | — | — | 0.140 | 0.063 | 0.031 | 0.017 | 0.011 |
| | 8 | — | — | 0.157 | 0.059 | 0.023 | 0.010 | 0.005 | 0.003 |

TABLE 8

| | | a₀n₁/λ | | | | | | | |
|---|---|---|---|---|---|---|---|---|---|
| (n₁ − n₀)/n₁ = 0.03 | | 0.35 | 0.5 | 0.75 | 1 | 1.25 | 1.5 | 1.75 | 2 |
| (Dn₁/λ) × | 1 | — | — | — | — | — | — | — | — |
| (a₀n₁/λ) | 2 | — | — | — | — | — | — | — | — |
| | 3 | — | — | — | — | 0.398 | 0.255 | 0.177 | 0.130 |
| | 4 | — | — | — | 0.156 | 0.076 | 0.042 | 0.026 | 0.018 |
| | 5 | — | — | 0.104 | 0.036 | 0.014 | 0.007 | 0.004 | 0.002 |
| | 6 | — | 0.119 | 0.032 | 0.008 | 0.003 | 0.001 | 0.001 | <0.001 |
| | 7 | 0.102 | 0.054 | 0.010 | 0.002 | <0.001 | <0.001 | <0.001 | <0.001 |
| | 8 | 0.063 | 0.024 | 0.003 | <0.001 | <0.001 | <0.001 | <0.001 | <0.001 |

TABLE 9

| | | a₀n₁/λ | | | | | | | |
|---|---|---|---|---|---|---|---|---|---|
| (n₁ − n₀)/n₁ = 0.04 | | 0.35 | 0.5 | 0.75 | 1 | 1.25 | 1.5 | 1.75 | 2 |
| (Dn₁/λ) × | 1 | — | — | — | — | — | — | — | — |
| (a₀n₁/λ) | 2 | — | — | — | — | 0.447 | 0.304 | 0.222 | 0.171 |
| | 3 | — | — | 0.214 | 0.089 | 0.043 | 0.024 | 0.016 | 0.011 |
| | 4 | — | 0.138 | 0.036 | 0.010 | 0.004 | 0.002 | 0.001 | 0.001 |
| | 5 | 0.095 | 0.040 | 0.006 | 0.001 | <0.001 | <0.001 | <0.001 | <0.001 |
| | 6 | 0.043 | 0.012 | 0.001 | <0.001 | <0.001 | <0.001 | <0.001 | <0.001 |
| | 7 | 0.019 | 0.003 | <0.001 | <0.001 | <0.001 | <0.001 | <0.001 | <0.001 |
| | 8 | 0.009 | 0.001 | <0.001 | <0.001 | <0.001 | <0.001 | <0.001 | <0.001 |

TABLE 10

| | | a₀n₁/λ | | | | | | | |
|---|---|---|---|---|---|---|---|---|---|
| (n₁ − n₀)/n₁ = 0.05 | | 0.35 | 0.5 | 0.75 | 1 | 1.25 | 1.5 | 1.75 | 2 |
| (Dn₁/λ) × | 1 | — | — | — | — | — | — | — | — |
| (a₀n₁/λ) | 2 | — | — | — | 0.176 | 0.097 | 0.061 | 0.043 | 0.032 |
| | 3 | — | 0.135 | 0.035 | 0.011 | 0.005 | 0.002 | 0.001 | 0.001 |
| | 4 | 0.074 | 0.024 | 0.003 | 0.001 | <0.001 | <0.001 | <0.001 | <0.001 |
| | 5 | 0.023 | 0.004 | <0.001 | <0.001 | <0.001 | <0.001 | <0.001 | <0.001 |
| | 6 | 0.007 | 0.001 | <0.001 | <0.001 | <0.001 | <0.001 | <0.001 | <0.001 |
| | 7 | 0.002 | <0.001 | <0.001 | <0.001 | <0.001 | <0.001 | <0.001 | <0.001 |
| | 8 | 0.001 | <0.001 | <0.001 | <0.001 | <0.001 | <0.001 | <0.001 | <0.001 |

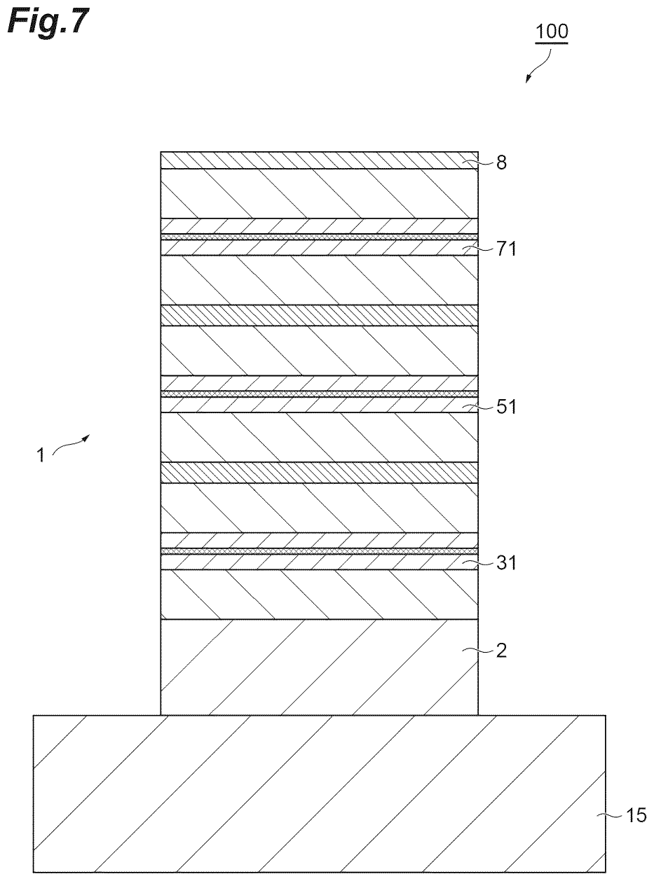

As shown in FIG. 7, the semiconductor laser element 1 can be mounted on a mount member 15 to form a laser module 100. That is, the laser module 100 includes the semiconductor laser element 1 and the mount member 15 on which the semiconductor laser element 1 is mounted. In the semiconductor laser element 1, the first emitter 31, the second emitter 51 and the third emitter 71 are stacked on the substrate 2 so that the first emitter 31 is located on the first side (the lower side in FIG. 7) closer to the substrate 2 than the second emitter 51, and the second emitter 51 is located closer to the first side than the third emitter 71. The semiconductor laser element 1 is fixed on the mount member 15 on the first side. The semiconductor laser element 1 is joined to the mount member 15 by soldering, for example. The mount member 15 is, for example, a heat sink made of copper. Since the semiconductor laser element 1 tends to generate a large amount of heat by having a plurality of emitters, it is preferable to ensure heat dissipation with a heat sink.

The effective refractive indices of the first emitter 31, the second emitter 51, and the third emitter 71 (an optical waveguide) are affected by the distortion occurring in them. Therefore, the difference in the effective refractive index introduced by making the thicknesses of the first emitter 31, the second emitter 51 and the third emitter 71 different can be canceled by the effect of the distortion. For example, in the semiconductor laser element 1, a stacked body (a stacked body configured of the first element part 3, the first tunnel junction layer 4, the second element part 5, the second tunnel junction layer 6, the third element part 7, and the cap layer 8) formed on the substrate 2 by the epitaxial growth method has a compressive strain in an in-plane direction due to a force acting from the substrate 2. When the compressive strain is present in the in-plane direction, the effective refractive index of the TE mode is changed to decrease. Since the strain is relaxed as a distance from the substrate 2 increases, the effective refractive index of a layer farther from the substrate 2 is relatively higher. Therefore, it is preferable to increase the thickness of the emitter farther from the substrate 2 so that the effective refractive index when it is present alone becomes larger, that is, the propagation constant becomes larger. In this regard, in the laser module 100, the second emitter 51 is thicker than the first emitter 31, and the third emitter 71 is thicker than the second emitter 51. Thus, the thicknesses of the first emitter 31, the second emitter 51, and the third emitter 71 are modulated in a direction in which the difference in the effective refractive index caused by the strain is emphasized. As a result, it is possible to avoid a situation in which the effect of curbing the light interference described above is impaired due to the influence of the strain generated in the first emitter 31, the second emitter 51, and the third emitter 71 by the force acting from the substrate 2.

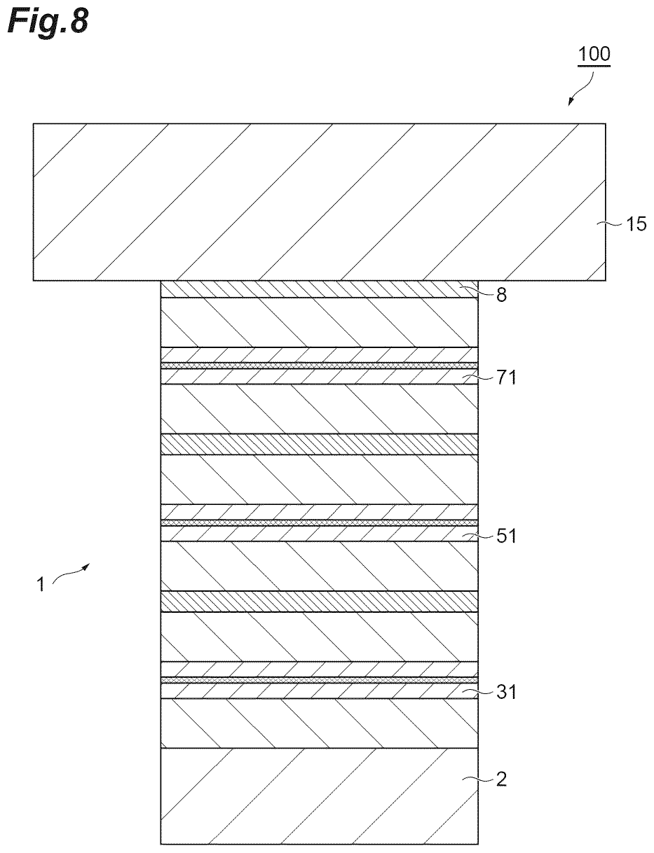

In the laser module 100 shown in FIG. 8, the semiconductor laser element 1 is fixed on the mount member 15 on the second side opposite to the first side (the upper side in FIG. 8). The mount member 15 is made of a material having a thermal expansion coefficient smaller than that of the substrate 2, and the thermal expansion coefficient of the mount member 15 is smaller than that of the substrate 2. In this case, the strain generated in the stacked body on the substrate 2 can become smaller as the distance from the substrate 2 increases. This is because the effect of the force acting on the stacked body from the substrate 2 due to a difference in a lattice constant is greater than the effect of the force acting on the stacked body from the mount member 15 due to the difference in the thermal expansion coefficient, or the directions of the forces are opposite. In the laser module 100, since the second emitter 51 is thicker than the first emitter 31, and the third emitter 71 is thicker than the second emitter 51, it is possible to avoid a situation in which the above-described effect of curbing light interference is impaired due to the influence of the strain generated in the first emitter 31, the second emitter 51, and the third emitter 71 by the forces acting from the substrate 2 and the mount member 15.

As another modified example, in the laser module 100 shown in FIG. 8, the thermal expansion coefficient of the mount member 15 may be larger than that of the substrate 2. In this modified example, the first emitter 31 is made thicker than the second emitter 51, and the second emitter 51 is made thicker than the third emitter 71. When the thermal expansion coefficient of the mount member 15 is larger than that of the substrate 2, the effect of the force acting on the stacked body from the mount member 15 is greater than the effect of the force acting on the stacked body from the substrate 2, and the strain generated in the stacked body may increase as the distance from the substrate 2 increases. In the laser module 100 of this modified example, since the first emitter 31, the second emitter 51 and the third emitter 71 are thick in this order, it is possible to avoid the situation in which the above-described effect of curbing light interference is impaired due to the influence of the strain generated in the first emitter 31, the second emitter 51, and the third emitter 71 by the forces acting from the substrate 2 and the mount member 15.

The present disclosure is not limited to the above embodiment and modified examples. For example, the material and shape of each configuration are not limited to the materials and shapes described above, and various materials and shapes can be adopted. In the above embodiment, the thickness of the first emitter 31 may be different from the thickness of the second emitter 51 by the thickness of the first active layer 32 being different from the thickness of the second active layer 52. In this case, the total thickness of the first guide layers 33 and 34 may be equal to the total thickness of the second guide layers.

Although the thicknesses of the first emitter 31, the second emitter 51 and the third emitter 71 are different from each other in the above embodiment, it is sufficient that at least two emitters have different thicknesses. From the viewpoint of curbing the interference, it is preferable that the thicknesses are different between the adjacent first emitters 31 and second emitters 51 and between the adjacent second emitters 51 and third emitters 71. In the above embodiment, the first emitter 31 is thinner than the second emitter 51, and the third emitter 71 is thicker than the second emitter 51, but the first emitter 31 and the third emitter 71 may be thinner than the second emitter 51. For example, the thicknesses of the first emitter 31 and the third emitter 71 may be equal to each other. Alternatively, the first emitter 31 and the third emitter 71 may be thicker than the second emitter 51. Although three emitters (waveguides) including the first emitter 31, the second emitter 51, and the third emitter 71 are provided in the above embodiment, four or more emitters may be provided. The first active layer 32, the second active layer 52, and the third active layer 72 may have a multiple quantum well structure. In this case, the thickness of the barrier layer may be changed as appropriate.

### REFERENCE SIGNS LIST

1: Semiconductor laser element, 2: Substrate, 15: Mount member, 31: First emitter, 32: First active layer, 33, 34: First guide layer, 35, 36: First clad layer, 51: Second emitter, 52: Second active layer, 53, 54: Second guide layer, 55, 56: Second clad layer, 71: Third emitter, 72: Third active layer, 73, 74: Third guide layer, 100: Laser module, D1: Optical axis direction, D2: Stacking direction

1: A semiconductor laser element comprising:
a first element part; and
a second element part stacked on the first element part in a stacking direction,
wherein the first element part includes a first emitter that includes a first active layer and a pair of first guide layers sandwiching the first active layer, and emits light along an optical axis direction, and a pair of first clad layers that sandwich the pair of first guide layers,
the second element part includes a second emitter that includes a second active layer and a pair of second guide layers sandwiching the second active layer, and emits light along the optical axis direction, and a pair of second clad layers that sandwich the pair of second guide layers, and
a thickness of the first emitter is different from a thickness of the second emitter so that an average value of an index DB1 represented by Equation (1) and an index DB2 represented by Equation (2) is 5% or less,
[Equation 1]
DB1=∫|F₁(θ)−F₀₁(θ)|dθ (1)
[Equation 2]
DB2=∫|F₂(θ)−F₀₂(θ)|dθ (2)
in Equation (1) and Equation (2), θ is an angle with respect to the optical axis direction, F₁(θ), F₂(θ), F₀₁(θ) and F₀₂(θ) are normalized far field patterns in the stacking direction, F₁(θ) is a far field pattern of light emitted from the first emitter when it is assumed that the second emitter is not present and only the first emitter is present, and F₂(θ) is a far field pattern of light emitted from the second emitter when it is assumed that the first emitter is not present and only the second emitter is present, and
when only the first emitter and second emitter are present, and it is assumed that, among two modes corresponding to a fundamental mode of the light emitted from the first emitter and the second emitter, a mode with a smaller propagation constant is defined as a first mode, and a mode with a larger propagation constant is defined as a second mode,
F₀₁(θ) is a far field pattern in the first mode, and F₀₂(θ) is a far field pattern in the second mode when the thickness of the first emitter is thinner than the thickness of the second emitter, and
F₀₁(θ) is a far field pattern in the second mode, and F₀₂(θ) is the far field pattern in the first mode when the thickness of the first emitter is thicker than the thickness of the second emitter.

2: The semiconductor laser element according to claim 1, wherein the thickness of the first emitter is different from the thickness of the second emitter so that the average value of the index DB1 and the index DB2 is 3% or less.

3: The semiconductor laser element according to claim 1, wherein the thickness of the first emitter is different from the thickness of the second emitter so that the average value of the index DB1 and the index DB2 is 1% or less.

4: The semiconductor laser element according to claim 1, wherein the thickness of the first emitter is different from the thickness of the second emitter by a total thickness of the pair of first guide layers being different from a total thickness of the pair of second guide layers.

5: The semiconductor laser element according to claim 1, wherein the thickness of the first emitter is different from the thickness of the second emitter so that an index P represented by Equation (3) is 25 or more,
[Equation 3]
P=|β₁−β₂|K₁₂ (3)
in Equation (3), β₁ is a propagation constant of the first emitter, β₂ is a propagation constant of the second emitter, and K₁₂ is a coupling constant between the first emitter and the second emitter when it is assumed that the thickness of each of the first emitter and the second emitter is equal to an average thickness of the first emitter and the second emitter.

6: The semiconductor laser element according to claim 5, wherein the thickness of the first emitter is different from the thickness of the second emitter so that the index P is 40 or more.

7: The semiconductor laser element according to claim 5, wherein the thickness of the first emitter is different from the thickness of the second emitter so that the index P is 125 or more.

8: The semiconductor laser element according to claim 1, wherein an absolute difference between the thickness of the first emitter and the average thickness of the first emitter and the second emitter is 10% or less of the average value.

9: The semiconductor laser element according to claim 1, further comprising a third element part stacked on the second element part in the stacking direction,
wherein the third element part includes a third emitter that includes a third active layer and a pair of third guide layers sandwiching the third active layer, and emits light along the optical axis direction, and a pair of third clad layers sandwiching the pair of third guide layers, and
a thickness of the third emitter is different from the thickness of the second emitter so that an average value of an index DB3 represented by Equation (4) and an index DB4 represented by Equation (5) is 5% or less,
[Equation 4]
DB3=∫|F₃(θ)−F₀₃(θ)|dθ (4)
[Equation 5]
DB4=∫|F₄(θ)−F₀₄(θ)|dθ (5)
in Equation (4) and Equation (5), F₃(θ) is a far field pattern of light emitted from the third emitter when it is assumed that the first and second emitters are not present and only the third emitter is present, and F₄(θ) is a far field pattern of light emitted from the second emitter when it is assumed that the first and third emitters are not present and only the second emitter is present, and
when the first emitter is not present and only the second emitter and the third emitter are present and it is assumed that, among two modes corresponding to a fundamental mode of the light emitted from the second emitter and the third emitter, a mode with a smaller propagation constant is defined as a third mode, and a mode with a larger propagation constant is defined as a fourth mode,
F₀₃(θ) is a far field pattern in the third mode, and F₀₄(θ) is a far field pattern in the fourth mode when the thickness of the third emitter is thinner than the thickness of the second emitter, and
F₀₃(θ) is a far field pattern in the fourth mode, and F₀₄(θ) is a far field pattern in the third mode when the thickness of the third emitter is thicker than the thickness of the second emitter.

10: The semiconductor laser element according to claim 1, further comprising a substrate,
wherein the first emitter and the second emitter are stacked on the substrate so that the first emitter is located on a first side closer to the substrate than the second emitter, and
the thickness of the first emitter is thinner than the thickness of the second emitter.

11: A laser module comprising:
the semiconductor laser element according to claim 10; and
a mount member on which the semiconductor laser element is mounted,
wherein the semiconductor laser element is fixed to the mount member on a second side opposite to the first side, and
a thermal expansion coefficient of the mount member is smaller than a thermal expansion coefficient of the substrate.

12: A laser module comprising:
the semiconductor laser element according to claim 1; and
a mount member on which the semiconductor laser element is mounted,
wherein the semiconductor laser element further includes a substrate,
the first emitter and the second emitter are stacked on the substrate so that the first emitter is located on a first side closer to the substrate than the second emitter,
the semiconductor laser element is fixed to the mount member on a second side opposite to the first side,
a thermal expansion coefficient of the mount member is larger than a thermal expansion coefficient of the substrate, and
the thickness of the first emitter is thicker than the thickness of the second emitter.

13: A semiconductor laser element comprising:
a first element part; and
a second element part stacked on the first element part in a stacking direction,
wherein the first element part includes a first emitter that includes a first active layer and a pair of first guide layers sandwiching the first active layer, and emits light along an optical axis direction, and a pair of first clad layers sandwiching the pair of first guide layers,
the second element part includes a second emitter that is stacked on the first emitter in the stacking direction, includes a second active layer and a pair of second guide layers sandwiching the second active layer, and emits light along the optical axis direction, and a pair of second clad layers sandwiching the pair of second guide layers, and
a thickness of the first emitter is different from a thickness of the second emitter so that an index P represented by Equation (6) is 25 or more,
[Equation 6]
P=|β₁−β₂|/K₁₂ (6)
in Equation (6), β₁ is a propagation constant of the first emitter, β₂ is a propagation constant of the second emitter, and K₁₂ is a coupling constant between the first emitter and the second emitter when it is assumed that the thickness of each of the first emitter and the second emitter is equal to an average thickness of the first emitter and the second emitter.
